(19) United States
(12) Patent Application Publication
(10) Pub. No.: US 2019/0341262 A1
(43) Pub. Date: Nov. 7, 2019

(54) METHOD FOR ELIMINATING DISLOCATIONS IN ACTIVE AREA AS WELL AS SEMICONDUCTOR DEVICE

(71) Applicant: WUHAN XINXIN SEMICONDUCTOR MANUFACTURING CO., LTD., Wuhan (CN)

(72) Inventors: Qingwei LUO, Wuhan (CN); Jingjing XU, Wuhan (CN); Yun LI, Wuhan (CN); Jun ZHOU, Wuhan (CN)

(21) Appl. No.: 16/204,374

(22) Filed: Nov. 29, 2018

(30) Foreign Application Priority Data
May 4, 2018 (CN) 201810420914.1

(51) Int. Cl. H01L 21/265; H01L 21/324; H01L 21/8238; H01L 29/08

(52) U.S. Cl. CPC H01L 21/26506; H01L 21/26586; H01L 29/0847; H01L 21/823807; H01L 21/324

(57) ABSTRACT

A method for eliminating dislocations in an active area and a semiconductor device are disclosed. The method includes: providing a substrate containing the active area; forming source and drain regions in the active area through implanting arsenic therein by a low-energy implantation process under conditions including an implantation energy of 3 kV-30 kV; and performing an annealing process. In the method and semiconductor device of the present invention, the source and drain regions are formed in the active area by low-energy implantation of arsenic. In this way, by optimizing implantation condition of the source and drain, less lattice mismatch in the active area will occurred. Such effective inhibition of lattice dislocations can reduce the occurrence of leakage current. Further, with the recovery by the annealing process, dislocations in the active area can be further reduced, allowing improved performance of the final product.

### CROSS-REFERENCE TO RELATED APPLICATION

This application claims the priority of Chinese patent application number 201810420914.1, filed on May 4, 2018, the entire contents of which are incorporated herein by reference.

### TECHNICAL FIELD

The present invention relates to the fabrication of integrated circuits (ICs) and, in particular, to a method for eliminating dislocations in an active area and to a semiconductor device.

### BACKGROUND

Increasing device miniaturization in IC design and continuous advancement of fabrication technology have brought about the need for corresponding dimensional shrinkage of semiconductor devices' active areas and even of their channels so as to achieve a continuous scaling down.

However, reduced active area and channel size can intensify the impact of a stress between source and drain on device performance and may cause dislocations and other adverse effects that may lead to leakage currents. With semiconductor devices becoming smaller and smaller, this issue is increasingly non-negligible.

Therefore, there is an urgent need in the art to develop a method for eliminating dislocations.

### SUMMARY OF THE INVENTION

In order to address the issue of dislocations in current semiconductor devices, it is an object of the present invention to provide a method for eliminating dislocations in an active area and a semiconductor device.

To this end, the method provided in the invention comprises:

providing a substrate which contains the active area;

forming source and drain regions in the active area through implanting arsenic in the substrate by a low-energy implantation process with an implantation energy of 3 kV-30 kV; and

performing an annealing process.

Optionally, in the method, the annealing process may be performed under an annealing temperature of 800° C.-1100° C. for 1 ms to 20 s.

Optionally, in the method, the substrate may be provided with spacers which are located outside the active area.

Optionally, in the method, the spacer may have a side wall slanted toward the active area at so that an angle of less than 80°.

Optionally, in the method, the spacer may be formed by a shallow trench isolation (STI) process.

Optionally, in the method, the spacer is formed of a material comprising silicon dioxide and/or silicon nitride.

Optionally, in the method, a top surface of the spacer may be higher than a top surface of the active area.

Optionally, in the method, the substrate may be further provided with a gate on a top surface thereof and a gate oxide layer arranged between the gate and the substrate.

Optionally, in the method, the substrate may be further provided with lightly doped drain (LDD) regions in the active area, and each of the LDD regions is located on a corresponding side of the gate.

Optionally, in the method, the arsenic is implanted in substrate by bombarding an arsenic target with an ion beam.

Optionally, in the method, the annealing process is performed under a certain degree of vacuum or a protective atmosphere of a high purity gas.

Optionally, in the method, the high purity gas is nitrogen or argon.

Optionally, in the method, the LDD regions are located between the source region and the gate as well as between the drain region and the gate respectively.

The semiconductor device provided in the present invention comprises source and drain regions formed by the method as define above.

In summary, in the method and semiconductor device of the present invention, the source and drain regions are formed in the active area by low-energy implantation of arsenic. In this way, implantation condition of the source and drain of the device might be optimized so that less lattice mismatch in the active area will be generated. The effective inhibition of lattice dislocations can reduce the occurrence of leakage current. Further, with the recovery by the annealing process, dislocations in the active area can be further reduced, allowing improve performance of the final product.

### BRIEF DESCRIPTION OF THE DRAWINGS

FIG. 1 is a flowchart of a method for eliminating dislocations in an active area according to an embodiment of the present invention.

FIGS. 2 to 3 show schematic cross-sectional views of a semiconductor device according to an embodiment of the present invention.

In these figures: 10, a substrate; 11, an active area; 12, a source or drain region; 20, a spacer; 30, a gate; 31, a gate oxide layer; and 40, a lightly-doped region.

### DETAILED DESCRIPTION

Reference is now made to the accompanying drawings for a better understanding of objects, features and advantages of the present invention. It should be noted that architectural, proportional, dimensional and other details in the figures are presented only for the purpose of facilitating, in conjunction with the disclosure herein, the understanding and reading of those familiar with the art rather than being intended to limit conditions under which the present invention can be implemented. Therefore, they are technically of no substantive significance, and any and all architectural modifications, proportional variations or dimensional changes that do not affect the benefits and objects of the present invention are considered to fall within the scope of the teachings herein.

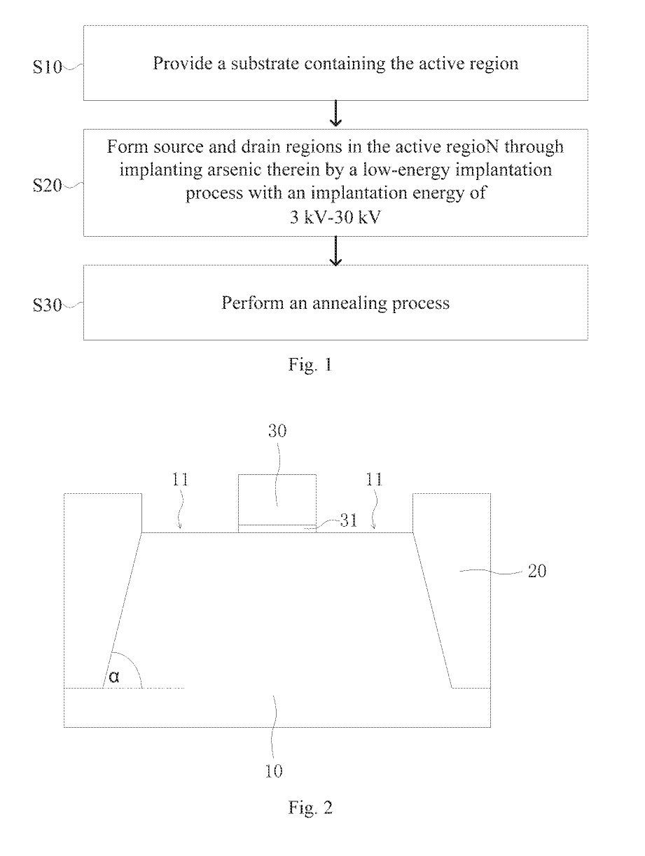

As shown in FIG. 1, the present invention provides a method for eliminating dislocations in an active area, including the steps of:

S10: providing a substrate which contains the active area;

S20: forming source and drain regions in the active area through implanting arsenic in the substrate by a low-energy implantation process under conditions including an implantation energy of 3 kV-30 kV; and

S30: performing an annealing process.

Particular embodiments of the present invention will be described in detail below with reference to the accompanying drawings so that features and advantages of the invention will become more apparent and be readily understood.

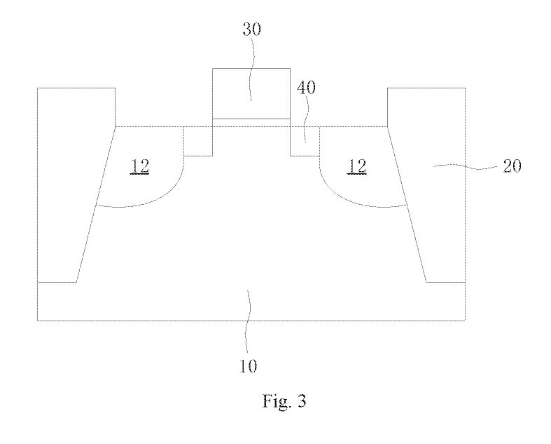

Referring now to FIG. 2, in step S10, a substrate 10 is provided, which may be any one of the various semiconductor materials well known to those skilled in the art, such as monocrystalline or polycrystalline silicon or germanium or a compound semiconductor such as silicon carbide, indium antimonide, gallium nitride, etc. It will be appreciated that, in addition to the active area 11, various semiconductor structures, devices and wirings may also have been formed on the semiconductor substrate. The active area is provided in order for the source and drain regions to be subsequently formed therein and is not limited to any particular size according to this application.

In the embodiment illustrated in FIG. 2, spacers 20 may be formed on the substrate 10, which are located at an outer side of the active area 11 and laterally surrounds the active area 11. Alternatively, the spacer may consist of multiple segments distributed on side walls of the active area. The spacer provides isolation capabilities for avoiding adverse effects that may arise from the doping process, such as stress or leakage current in the active area.

The spacer may have a surface slanted toward the active area 11 so that an angle α of less than 80°, for example, 70°, 60°, 50°, 45°, etc. In other words, the spacer 20 is tapered from the top downward. This design enables stronger isolation by the upper portion of the active area that is subject to greater impacts from other doping processes performed on the active area 11.

Optionally, the spacer 20 may be formed by a shallow trench isolation (STI) process of a material including silicon dioxide (SiO₂) and/or silicon nitride (Si₃N₄).

In order for better isolation to be achieved, the spacer 20 may be higher than the active area 11. The spacer structure may be accomplished by the STI process including: forming an etch stop layer over the substrate; etching the etch stop layer and the substrate to create a trench; filling the trench with a dielectric material such as SiO₂ or Si₃N₄; and removing the etch stop layer.

According to one embodiment, a gate 30 may be formed on the substrate, which include a gate oxide layer 31 attached to the surface of the substrate 10. That is, the gate 30 may be a floating gate. When there is no electron injected into the floating gate, electrons in the floating gate will be driven into an upper portion of the floating gate by a voltage applied on a control gate, leaving holes in a lower portion of the floating gate. Electrons will be attracted into the holes by induction, thus creating a conductive channel between the source and drain. On the contrary, when electrons are injected into the floating gate, the threshold voltage of the transistor will be increased, leading elimination of the channel. In this way, the channel between the source and drain can be turned on or off like a switch.

In step S20, source and drain regions 12 are formed in the active area 11 through implanting arsenic therein by carrying out a low-energy implantation process. The arsenic implantation in the active area may be accomplished by bombarding an arsenic target with an ion beam. The low-energy implantation process can be carried out under conditions including an implantation energy of 3 kV-30 kV. As this low-energy arsenic implantation process can reduce the lattice defects in the active area, fewer lattice defects in the active region will be generated through the optimized condition of the source and drain implantation. As a result, the occurrence of leakage current in the resulting device can be reduced.

In step S30, an annealing process is carried out. This annealing process can recover lattice crystallinity and eliminate defects. Moreover, it can also activate the dopant, i.e., causing dopant atoms in gaps diffuse into substitutional positions. Further, it can recover the lifetime and mobility of minority carriers.

Optionally, the annealing process may be carried out under conditions including: an annealing temperature of 800° C.-1100° C.; an annealing duration of 1 ms to 20 s; and a certain degree of vacuum or a protective atmosphere of nitrogen, argon or another high purity gas. For example, depending on the requirements of the resulting device, a rapid thermal processing (RTP) process can be performed for a short period of time ranging from 1 ms to 20 s. Such a process offers the advantages of less migration of dopant atoms in the substrate, less contamination and a shorter process time. Specifically, the annealing temperature may be any temperature in the range of 800° C.-1100° C., such as 800° C., 900° C., 1000° C. or 1100° C.

As shown in FIG. 3, lightly doped drain (LDD) regions 40 may be further formed on the substrate 10 on both sides of the gate 30 near the channel, i.e., between the source region 12 and the gate as well as between the drain region and gate. The LDD regions 40 can weaken an electric field between the source and drain regions 12, thereby alleviating thermal electron degradation. This is because the LDD regions 40 disposed in the channel and in the vicinity of the drain and drain regions can share part of the voltage. As a result, thermal electron degradation is mitigated. Here, the term “lightly-doped” is used with respect to the doping concentration of the source and drain regions.

The present invention also provides a corresponding semiconductor device comprising source and drain regions fabricated by the method as defined above. As the source and drain regions formed by low-energy implantation of arsenic suffer from fewer dislocations, the occurrence of leakage current in the semiconductor device is reduced, resulting in an improved performance of the product and a higher yield of its production.

In summary, in the method and semiconductor device of the present invention, the source and drain regions are formed in the active area by low-energy implantation of arsenic. In this way, by optimizing the condition of the source and drain implantation, less lattice mismatch in the active area will occur. The effective inhibition of lattice dislocations can reduce the occurrence of leakage current. Further, with the recovery by the annealing process, dislocations in the active area can be further reduced, allowing improve performance of the final product.

The description presented above is merely that of some preferred embodiments of the present invention and does not limit the scope thereof in any sense. Any and all changes and modifications made by those of ordinary skill in the art based on the above teachings fall within the scope as defined in the appended claims.

What is claimed is:

1. A method for eliminating dislocations in an active area, comprising:
providing a substrate which contains an active area;
forming source and drain regions in the active area through implanting arsenic in the substrate by a low-energy implantation process with an implantation energy of 3 kV-30 kV; and
performing an annealing process.

2. The method of claim 1, wherein the annealing process is performed under an annealing temperature of 800° C.-1100° C. for 1 ms to 20 s.

3. The method of claim 1, wherein the substrate is provided with spacers which are located outside the active area.

4. The method of claim 3, wherein the spacer has a side wall slanted toward the active area so that an angle of smaller than 80° is formed.

5. The method of claim 3, wherein the spacer is formed by a shallow trench isolation (STI) process.

6. The method of claim 5, wherein a top surface of the spacer is higher than a top surface of the active area.

7. The method of claim 1, wherein the substrate is further provided with a gate on a top surface thereof and a gate oxide layer arranged between the gate and the substrate.

8. The method of claim 7, wherein the substrate is further provided with lightly doped drain (LDD) regions in the active area, and each of the LDD regions is located on a corresponding side of the gate.

9. The method of claim 3, wherein the spacer is formed of a material comprising silicon dioxide and/or silicon nitride.

10. The method of claim 1, wherein the arsenic is implanted in the substrate by bombarding an arsenic target with an ion beam.

11. The method of claim 1, wherein the annealing process is performed under a certain degree of vacuum or a protective atmosphere of a high purity gas.

12. The method of claim 11, wherein the high purity gas is nitrogen or argon.

13. The method of claim 8, wherein the LDD regions are located between the source region and the gate as well as between the drain region and the gate respectively.

14. A semiconductor device, comprising source and drain regions formed by the method of claim 1.
